(19) United States
(12) Patent Application Publication
(10) Pub. No.: US 2012/0196433 A1
(43) Pub. Date: Aug. 2, 2012

(54) METHOD OF MANUFACTURING A SEMICONDUCTOR DEVICE

(76) Inventors: Jeong-Hee Han, Hwaseong-si (KR); Hyeok-Jun Son, Seoul (KR); Sang-Jin Hyun, Suwon-si (KR); Hoon-Joo Na, Gyeonggi-do (KR)

(21) Appl. No.: 13/208,978

(22) Filed: Aug. 12, 2011

(30) Foreign Application Priority Data
Feb. 1, 2011 (KR) 10-2011-0010344

(51) Int. Cl. H01L 21/28; H01L 21/311; H01L 21/263

(52) U.S. Cl. 438/591; 438/703; 438/585; 257/E21.333; 257/E21.19; 257/E21.249

(57) ABSTRACT

Provided is a manufacturing method for a semiconductor device having reduced leakage current and increased capacitance while improving interface characteristics. The manufacturing method includes forming a silicon oxide layer on a base layer including silicon, forming a silicon oxynitride layer by implanting nitrogen into the silicon oxide layer, and forming hydroxy groups on a surface of the silicon oxynitride layer while etching the silicon oxynitride layer.

### CROSS-REFERENCE TO RELATED APPLICATIONS

This application claims priority of Korean Patent Application No. 10-2011-0010344 filed on Feb. 1, 2011 in the Korean Intellectual Property Office, and all the benefits accruing therefrom under 35 U.S.C. 119, the contents of which in its entirety are herein incorporated by reference.

### BACKGROUND

1. Field of the Invention

The present disclosure relates to a method of manufacturing a semiconductor device, and more particularly to a manufacturing method for a semiconductor device having reduced leakage current and increased capacitance while improving interface characteristics.

2. Description of the Related Art

Silicon dioxide (SiO₂) has been used as gate dielectrics. As the integration density of a semiconductor device has recently been increasing, a thickness of a gate insulation layer should be continuously scaled down. However, since the silicon dioxide has a low dielectric constant (k) of approximately 3.9, further scaling down of silicon dioxide gate dielectric has become more and more difficult. In addition, thinning the silicon dioxide gate dielectric layer may cause direct tunneling between a semiconductor substrate and a gate electrode. As a result, a leakage current through silicon dioxide gate dielectric layer having a reduced thickness may increase. Accordingly, recent studies are directed to using a high-k dielectric layer as gate dielectrics, which is capable of remarkably reducing a thickness of the high-k dielectric layer while maintaining the thickness at a level of a silicon oxide layer thickness enough to prevent the direct tunneling.

However, in a case where the high-k dielectric layer is used as the gate dielectrics, leakage current may be generated due to intrinsic defects of the high-k dielectric layer, and electron and hole mobility in a channel may decrease. In addition, deposition of the high-k dielectric layer may deteriorate interface characteristics between the high-k dielectric layer and the silicon substrate.

Accordingly, it would be desirable to develop a gate dielectric layer capable of improving interface characteristics between the high-k dielectric layer and the silicon substrate while reducing the leakage current and improving the capacitance.

### SUMMARY

The present disclosure provides a manufacturing method for a semiconductor device having reduced leakage current and increased capacitance while improving interface characteristics.

The above and other objects of the present disclosure will be described in or be apparent from the following description of the preferred embodiments.

According to one embodiment, there is provided a manufacturing method for a semiconductor device including forming a silicon oxide layer on a base layer including silicon, forming a silicon oxynitride layer by implanting nitrogen into the silicon oxide layer, and forming hydroxy groups on a surface of the silicon oxynitride layer while etching the silicon oxynitride layer.

According to another embodiment, there is provided a manufacturing method for a semiconductor device, including forming an insulation layer on the substrate; forming an interface layer by thermal treatment or plasma treatment to the insulation layer; forming hydroxy groups on a surface of the interface layer by treating the interface layer using an etching solution containing an oxygen source; forming a high-k dielectric layer on the interface layer; forming a conductive layer on the high-k dielectric layer; and forming a gate pattern by patterning the interface layer, the high-k dielectric layer and the conductive layer.

According to another embodiment, there is provided a manufacturing method of a semiconductor device including forming an insulation layer on a substrate, and forming hydroxy groups on a surface of the insulation layer.

According to yet another embodiment, there is provided a method of manufacturing a semiconductor device. The method includes forming a first interface layer on a substrate, the first interface layer including nitrogen; forming a second interface layer on the substrate by forming hydroxy groups on a surface of the first interface layer and by treating the first interface layer using an etching solution containing an oxygen source, wherein a distance between a peak nitrogen concentration at a first height within the first interface layer and a midpoint of the height of the first interface layer is greater than a distance between a peak nitrogen concentration at a second height within the second interface layer and a midpoint of the height of the second interface layer; forming a high-k dielectric layer on the second interface layer; forming a conductive layer on the high-k dielectric layer; and forming a gate pattern by patterning the second interface layer, the high-k dielectric layer and the conductive layer.

### BRIEF DESCRIPTION OF THE DRAWINGS

The above and other features and advantages of the present disclosure will become more apparent by describing in detail various embodiments thereof with reference to the attached drawings in which:

FIGS. 1 to 3 are cross-sectional views illustrating a method of manufacturing a semiconductor device according to an exemplary embodiment;

FIG. 4 is a cross-sectional view exaggerating A and B portions shown in FIG. 3, according to one exemplary embodiment;

FIG. 5 is a cross-sectional view sequentially illustrating processing steps of a manufacturing method for a semiconductor device according to an exemplary embodiment;

FIGS. 6 to 14 are cross-sectional views sequentially illustrating processing steps of a manufacturing method for a semiconductor device according to another exemplary embodiment;

FIGS. 15 to 17 are cross-sectional views sequentially illustrating processing steps of a manufacturing method for a semiconductor device according to another exemplary embodiment

FIG. 18 is a graph illustrating changes in the nitrogen concentration and interface layer thickness over the treatment time when an interface layer prepared in Example 1 is treated with an SC1 (standard clean 1) solution containing a mixture of ammonium hydroxide and hydrogen peroxide, according to one exemplary embodiment; and

FIG. 19 is a graph illustrating changes in the nitrogen concentration and interface layer thickness over treatment time when an interface layer prepared in Example 2 is treated with an SC1 (standard clean 1) solution containing a mixture of ammonium hydroxide and hydrogen peroxide, according to one exemplary embodiment.

### DETAILED DESCRIPTION OF THE EMBODIMENTS

Advantages and features of the present disclosure and methods of accomplishing the same may be understood more readily by reference to the following detailed description of various embodiments and the accompanying drawings. The present invention may, however, be embodied in many different forms and should not be construed as being limited to the embodiments set forth herein. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

As used herein, the singular forms “a”, “an” and “the” are intended to include the plural forms as well, unless the context clearly indicates otherwise.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

It will be further understood that the terms “comprises,” “including,” and/or “made of,” when used in this specification, specify the presence of stated features, integers, steps, operations, elements, and/or components, but do not preclude the presence or addition of one or more other features, integers, steps, operations, elements, components, and/or groups thereof.

Embodiments described herein will be described referring to plan views and/or cross-sectional views by way of ideal schematic views. Accordingly, the exemplary views may be modified depending on manufacturing technologies and/or tolerances. Therefore, the embodiments of the disclosure are not limited to those shown in the views, but include modifications in configuration formed on the basis of manufacturing processes. Therefore, regions exemplified in figures have schematic properties, and shapes of regions shown in figures exemplify specific shapes of regions of elements and do not limit aspects of the disclosure.

Terms such as “same,” “planar,” or “coplanar,” as used herein when referring to orientation, location, shapes, sizes, amounts, or other measures do not necessarily mean an exactly identical orientation, location, shape, size, amount, or other measure, but are intended to encompass nearly identical orientation, location, shapes, sizes, amounts, or other measures within acceptable variations that may occur, for example, due to manufacturing processes.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

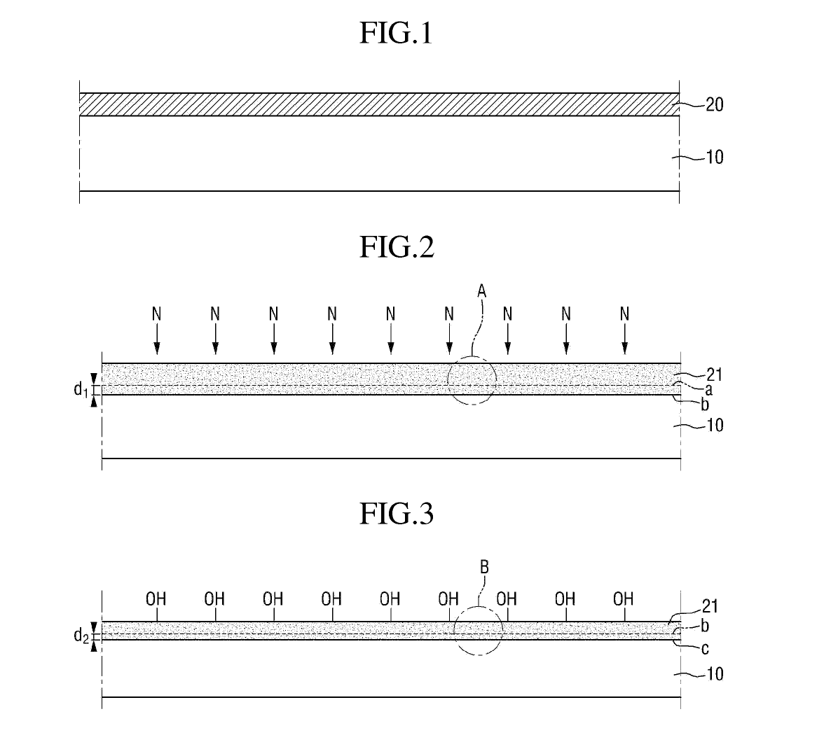

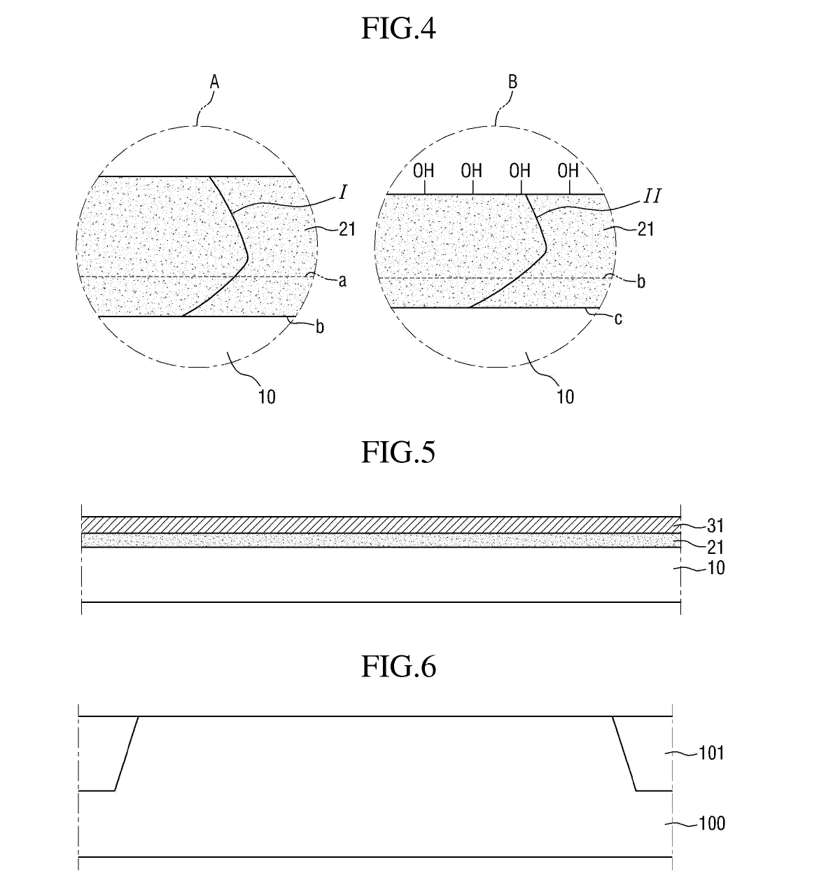

A manufacturing method for a semiconductor device according to one embodiment will be described with reference to FIGS. 1 to 5. FIGS. 1 to 3 are cross-sectional views illustrating a manufacturing method for a semiconductor device according to one embodiment, and FIG. 4 is a cross-sectional view exaggerating A portion shown in FIG. 2 and B portion shown in FIG. 3.

Referring to FIG. 1, a silicon oxide layer 20 is formed on a base layer 10.

In one embodiment, the base layer 10 includes silicon, and may include additional elements. Specifically, the base layer 10 may include, for example, a silicon substrate, a silicon on insulator (SOI) substrate, or a silicon germanium substrate, but is not limited thereto.

The silicon oxide layer 20 may be formed, in one embodiment, by thermally oxidizing a predetermined region close to a surface of the base layer 10. Specifically, for example, the silicon oxide layer 20 may be formed by performing thermal oxidation on the base layer 10 or performing a rapid thermal oxidation at a temperature of 700 to 1100° C., but not limited thereto. The oxygen atmosphere may be created by implanting hydrogen peroxide (H₂O₂), ozone (O₃) or water (H₂O), for example.

In another embodiment, the silicon oxide layer 20 may be formed by treating the base layer 10 with a chemical material. In detail, the base layer 10 may be treated with a solution containing, for example, an oxygen source and ammonia (NH₃) to oxidize a predetermined region of the base layer 10 by the oxygen source, thereby forming the silicon oxide layer 20. Hydrogen peroxide may be used as the oxygen source, but it is not limited thereto.

In addition, in another embodiment, the silicon oxide layer 20 may be formed by atomic layer deposition (ALD) or chemical vapor deposition (CVD). Non-limiting examples of the silicon source gas may include at least one selected from the group consisting of SiH₄, SiH₂Cl₂, SiHCl₃, SiCl₄, Si(OC₄H₉)₄, Si(OCH₃)₄ and Si(OC₂H₅)₄, either alone or in a mixture thereof, and non-limiting examples of the oxygen source gas may include at least one selected from the group consisting of H₂O, O₂, O₃, O radical, alcohol, and H₂O₂, either alone or in a mixture thereof.

In one embodiment, the silicon oxide layer 20 may be formed to a thickness of 5 to 10 Å. If the silicon oxide layer 20 is formed to a thickness of 5 Å or greater, an increase in the leakage current can be prevented and a sufficiently high dielectric constant can be achieved. In addition, if the silicon oxide layer 20 is formed to a thickness of 10 Å or less, the performance of the device can be improved.

Referring to FIG. 2, the silicon oxide layer 20 is subjected to nitridation by implanting nitrogen atoms into the silicon oxide layer 20, thereby forming a silicon oxynitride layer 21. The nitrogen implanting may increase a dielectric constant of the silicon oxide layer 20 and may further increase capacitance thereof.

In one embodiment, the nitridation may be performed by a rapid thermal annealing process on an object to be processed, having the silicon oxide layer 20 in a nitrogen source gas atmosphere. The nitridation is performed by a rapid thermal annealing process according to this embodiment, however, only the thermal annealing process may be performed without nitridation. Non-limiting examples of the nitrogen source gas may include a gas such as N₂, NH₃, N₂O or NO, a mixed gas containing the nitrogen source gas, halogen, or an oxygen containing gas. The rapid thermal annealing process is performed, in one embodiment, at a temperature, for example, in a range of 500° C. to 1000° C. for 10 to 30 seconds. For example, when ammonia (NH₃) is used as the nitrogen source gas, a N—H bond in ammonia is broken during the rapid thermal annealing process, and free nitrogen generated when the N—H bond in ammonia is broken is diffused into the silicon oxide layer 20 to the be combined with a weak bond having O—Si—O bonds and a dangling bond in the silicon oxide layer 20, thereby forming the silicon oxynitride layer 21.

In another embodiment, the nitridation may be performed by plasma treatment rather than the rapid thermal annealing process. In detail, plasma treatment may be performed for 5 to 300 seconds by implanting a nitrogen source gas and applying RF source power of 100 to 1000 W while maintaining the object to be processed having the silicon oxide layer 20 at a temperature ranging from 0° C. to 500° C. in a vacuum.

After the nitridation, a thickness of the silicon oxynitride layer 21 may be greater than that of the silicon oxide layer 20. In detail, since the interface between the base layer 10 and the silicon oxynitride layer 21 is shifted toward the base layer 10 from ‘a’ to ‘b’, the thickness of the silicon oxynitride layer 21 may be increased by d₁. The thickness of the silicon oxynitride layer 21 is increased due to regrowth of the silicon oxide layer 20 or additional oxidation caused by free oxygen. First, during the nitridation, nitrogen atoms combine with weak bonds or dangling bonds in the silicon oxide layer 20, allowing the silicon oxide layer 20 to regrow. Alternatively, nitrogen atoms may break a weak Si—O bond and oxygen displacement may occur thereat, thereby allowing free oxygens to be diffused into the interface between the base layer 10 and the silicon oxynitride layer 21, leading to additional oxidation.

A concentration distribution of nitrogen atoms implanted into the silicon oxide layer 20 will now be described with reference to FIG. 4. The left drawing of FIG. 4 is an exemplary cross-sectional view exaggerating a portion A of FIG. 2 after nitridation, in which the curve I represents a concentration distribution of induced nitrogen atoms. According to the nitrogen concentration distribution, the closer to the interface ‘a’ between the silicon oxide layer 20 and the base layer 10, the higher the nitrogen concentration becomes. The nitrogen concentration is highest near the interface ‘a’ between the silicon oxide layer 20 and the base layer 10. As a thickness of the silicon oxynitride layer 21 is increased due to the free oxygen diffused into the silicon base layer 10 during nitrogen implanting, the nitrogen concentration decreases gradually from the interface ‘a’ between the silicon oxide layer 20 and the base layer 10 to the interface ‘b’ between the silicon oxynitride layer 21 and the base layer 10

Referring to FIG. 3, hydroxy groups (OH) are formed on a surface of the silicon oxynitride layer 21 while etching the silicon oxynitride layer 21. As the result of the etching, the thickness of the silicon oxynitride layer 21 increased by nitrogen implanting is reduced, thereby improving the performance of the device. In addition, since the hydroxy groups (OH) are formed on the surface of the silicon oxynitride layer 21, interface characteristics can be improved in a subsequent process of depositing a high-k dielectric layer on the silicon oxynitride layer 21 by atomic layer deposition (ALD).

The silicon oxynitride layer 21 has a portion of top surface region etched back through chemical treatment and the hydroxy groups formed on its surface. In one embodiment, the chemical treatment may be performed using a chemical material capable of forming the hydroxy groups (OH) on the surface of the silicon oxynitride layer 21 while etching the silicon oxynitride layer 21. In detail, a mixed solution including ammonium hydroxide (NH₄OH) and hydrogen peroxide may be used as the chemical material, and the mixed solution may further include deionized water. The ammonium hydroxide and hydrogen peroxide may react with the silicon oxynitride layer 21 and etch the same. The hydrogen peroxide offers hydroxy groups on the surface of the silicon oxynitride layer 21.

Since the interface between the silicon oxynitride layer 21 and the base layer 10 is shifted from ‘b’ to ‘c,’ the thickness of the silicon oxynitride layer 21 is increased by d₂. This is because the oxygen atoms in the silicon oxynitride layer 21 are diffused into the base layer 10 by the chemical material used to etch the silicon oxynitride layer 21 and to offer hydroxy groups. However, even if the interface between the silicon oxynitride layer 21 and the base layer 10 is shifted toward the base layer 10, the overall thickness of the silicon oxynitride layer 21 is reduced due to the etching of the silicon oxynitride layer 21.

In one embodiment, after performing the above-described process, the silicon oxynitride layer 21 may have a thickness of 6.0 Å or less. If the thickness of the silicon oxynitride layer 21 is 6.0 Å or less, interface characteristics between the base layer 10 and a high-k dielectric layer stacked on the silicon oxynitride layer 21 can be improved while increasing a dielectric constant, compared to a case where the dielectric layer is a silicon oxide layer.

The concentration distribution of nitrogen atoms in the silicon oxynitride layer 21 will now be described with reference to FIG. 4. The right drawing of FIG. 4 is a cross-sectional view exaggerating a portion B of FIG. 3 in which the curve II represents a nitrogen concentration distribution. Referring to FIG. 4, once the hydroxy groups are formed on the surface of the silicon oxynitride layer 21 while etching the silicon oxynitride layer 21, the nitrogen concentration has a streamlined profile. For example, as shown in the embodiment of FIG. 4, the nitrogen concentration is highest in the center of the silicon oxynitride layer 21. That is to say, the nitrogen concentration decreases toward the upper surface or lower surface of the silicon oxynitride layer 21. This is because a region of the silicon oxynitride layer 21 corresponding to a top portion is etched and the interface between the silicon oxynitride layer 21 and the base layer 10 is shifted from ‘b’ to ‘c.’ In a case where the nitrogen concentration is highest nearer the interface between the silicon oxynitride layer 21 and the base layer 10, like in the A portion, interface characteristics may deteriorate and leakage current may be generated. Therefore, in one embodiment, the nitrogen concentration is distributed to have a streamlined profile, like in the B portion. As such, in one embodiment, a distance between a peak nitrogen concentration at a first height within the interface layer shown in A and a midpoint of the height of the interface layer shown in A is greater than a distance between a peak nitrogen concentration at a second height within the interface layer shown in B and a midpoint of the height of the interface layer shown in B. The nitrogen concentration can be adjusted by a chemical treatment time. As the chemical treatment time is extended, the silicon oxynitride layer 21 is etched so that its thickness is reduced and the nitrogen concentration is reduced. The chemical treatment time can be arbitrarily adjusted by one skilled in the art based on a desired thickness of the silicon oxynitride layer 21.

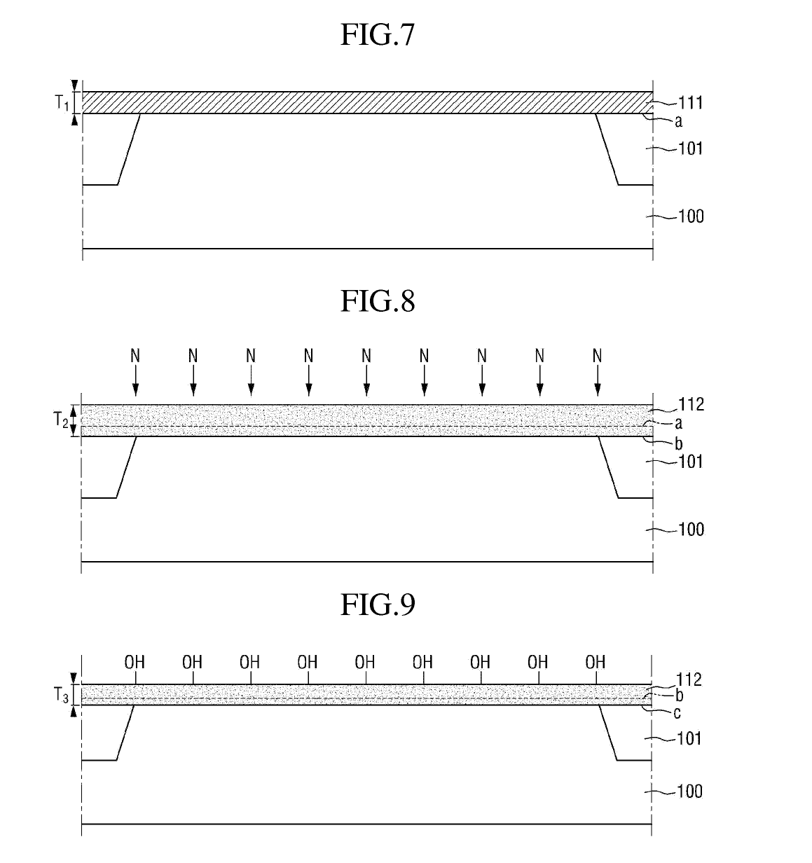

Referring to FIG. 5, a high-k dielectric layer 31 is formed on the silicon oxynitride layer 21. When the high-k dielectric layer 31 is deposited directly on the base layer 10, uniform deposition may not be performed due to poor interface characteristics between the high-k dielectric layer and the base layer 10, which may cause leakage current. In addition, the high-k dielectric layer 31 typically readily reacts with the base layer 10, forming an interface layer, thereby lowering the performance of the device. However, in the manufacturing method according to the disclosed embodiments, because the silicon oxynitride layer 21 is formed between the base layer 10 and the high-k dielectric layer 31 and the hydroxy groups are formed on the surface of the silicon oxynitride layer 21, deposition of the high-k dielectric layer 31 is easily achieved and the interface characteristics between the high-k dielectric layer 31 and the base layer 10 can be improved, thereby preventing leakage current.

The high-k dielectric layer 31 is a layer having a higher dielectric constant than the silicon oxynitride layer, and generally, according to certain embodiments, has a dielectric constant of 10 or higher. Examples of the high-k dielectric layer 31 include hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate, either alone or in a mixture thereof. In addition, the high-k dielectric layer 31 may have a single- or multi-layered structure including the above stated materials, and the structure type or thickness of the high-k dielectric layer 31 may be arbitrarily adjusted by one skilled in the related art so long as it does not negate the benefits and advantages of the disclosed embodiments.

The high-k dielectric layer 31 may be formed, for example, by atomic layer deposition (ALD). In detail, in one embodiment, a source gas based on a metal component, such as Hf, Zr, Al, Ti, La, Y, Gd or Ta, is implanted into the silicon oxynitride layer 21 to be adsorbed onto the silicon oxynitride layer 21. Here, hydroxy groups formed on the silicon oxynitride layer 21 are combined with the metal source gas and uniform adsorption occurs. Thereafter, a purge gas is injected to remove unreacted gas remaining in the source gas. For example, argon (Ar) or nitrogen gas may be used as the purge gas. Next, a reaction gas is injected to react with the metal source gas to form a high-k dielectric layer. For example, ozone (O₃), plasma oxygen, or water vapor (H₂O) may be used as the reaction gas.

As described above, in the manufacturing method of the semiconductor device according to certain embodiments, an interface layer having hydroxy group in the surface is formed between the base layer 10 and the high-k dielectric layer 31, thereby improving interface characteristics between the base layer 10 and the high-k dielectric layer 31 while facilitating deposition of the high-k dielectric layer 31. In addition, in case that the interface layer is made of silicon oxynitride, it has a higher dielectric constant than the silicon oxide layer, thereby achieving higher capacitance while reducing the leakage current.

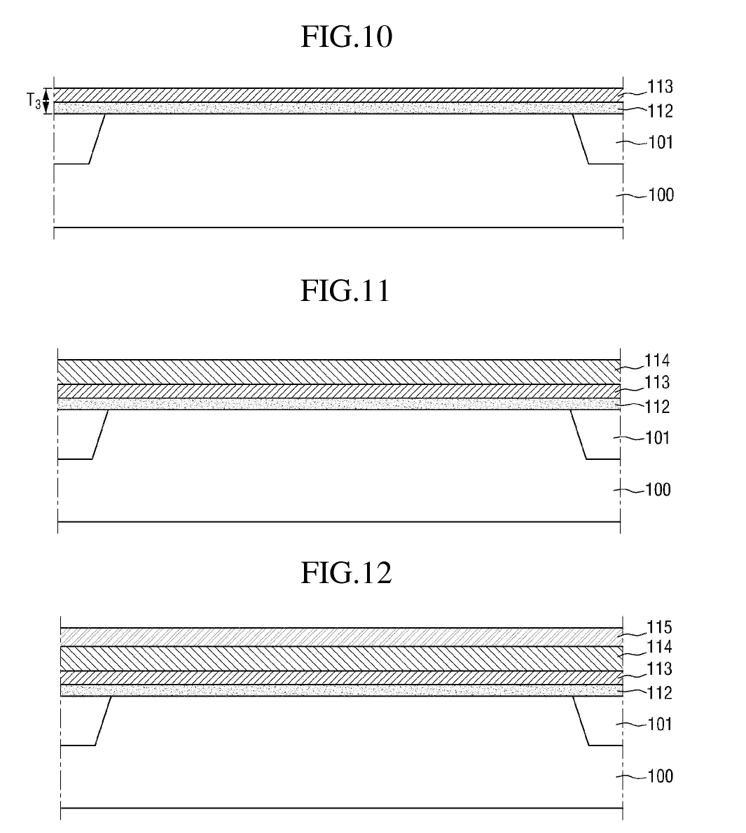

Hereinafter, a manufacturing method of a semiconductor device according to one exemplary embodiment will be described with reference to FIGS. 6 to 14. FIGS. 6 to 14 are cross-sectional views sequentially illustrating processing steps of an exemplary manufacturing method of a semiconductor device according to one embodiment.

Referring to FIG. 6, a device isolation region 101 is formed on a semiconductor substrate 100 to define an isolation region.

The semiconductor substrate 100 may include, for example, a silicon substrate, a silicon on insulator (SOI) substrate, a gallium arsenic substrate, a silicon germanium substrate, a ceramic substrate, a quartz substrate, or a glass substrate for a display, but is not limited thereto. In addition, the semiconductor substrate 100 may be a P-type substrate or an N-type substrate. Although not shown, the semiconductor substrate 100 may include a P-type well or an N-type well doped with p-type or n-type impurity.

The device isolation region 101 has the isolation region formed on the semiconductor substrate 100 to electrically isolate a device by preventing the device from being electrically connected to an active region. In detail, the device isolation region 101 may be formed by forming a trench by etching a predetermined region of the semiconductor substrate 100, filling the trench with an insulating material, and planarizing a top surface of the resultant structure. Examples of the insulating material may include an oxide layer, a high density plasma (HDP) oxide layer, or an undoped silicated glass (USG) layer. The planarzing may be performed by a chemical mechanical polishing (CMP) process. During the planarzing, a top surface of the device isolation region 101 may be elevated to a predetermined height from a top surface of the semiconductor substrate 100. This is for preventing electrical properties of the device from deteriorating because the top surface of the device isolation region 101 is lowered relative to the top surface of the semiconductor substrate 100 and thus the leakage current occurs at sidewalls of the device isolation region 101 in the course of etching in a subsequent process of the semiconductor device. In addition, the device isolation region 101 may also be formed by a FOX (Field Oxide) process by supplying O₂ gas to the semiconductor substrate 100 with heat energy to form an oxide layer through an oxidation reaction between silicon and oxygen.

Referring to FIG. 7, an insulation layer 111 is formed on the semiconductor substrate 100.

The insulation layer 111 serves to improve interface characteristics between an overlying high-k dielectric layer 113 to be described later and an underlying semiconductor substrate 100. In one embodiment, the insulation layer 111 is made of silicon oxide, but, if the semiconductor substrate 100 is made of a material other than silicon, another insulation layer may be used instead of the silicon oxide layer. In this case, a material capable of improving interface characteristics between an overlying high-k dielectric layer 113 to be described later and an underlying semiconductor substrate 100 should be used for the insulation layer 111.

In one embodiment, the insulation layer 111 may be formed on the semiconductor substrate 100 by injecting an oxygen containing gas into a furnace, followed by thermal oxidation. Alternatively, the insulation layer 111 may be formed by rapid thermal oxidation at a temperature, for example, in a range of approximately 700° C. to approximately 1100° C. in an oxygen atmosphere. The oxygen atmosphere may be created by injecting, for example, hydrogen peroxide (H₂O₂), ozone (O₃) or deionized water (H₂O). The thermal oxidation or the rapid thermal oxidation may be performed by a general method well known in the related art. A predetermined region of the surface of the semiconductor substrate 100 is oxidized by the method stated above, thereby forming the insulation layer 111.

The insulation layer 111 may also be formed by treating the semiconductor substrate 100 with an oxygen containing chemical material. For example, if the semiconductor substrate 100 is treated with a solution containing an oxygen source, the predetermined region of the semiconductor substrate 100 may be oxidized by the oxygen source to form the insulation layer 111. Here, hydrogen peroxide may be used as the oxygen source, but is not limited thereto. In addition, the oxygen source containing solution may further contain ammonia, water or ammonium hydroxide.

Alternatively, the insulation layer 111 may be formed by atomic layer deposition (ALD) or chemical vapor deposition (CVD). For example, in one embodiment, the insulation layer 111 is formed by ALD. First, a silicon source gas is activated as RF plasma or microwave plasma and supplied to then be adsorbed onto the semiconductor substrate 100 and surplus silicon source gas that is not adsorbed is purged. Next, an oxidation gas is supplied as a reaction gas to allow the adsorbed silicon source gas to chemically react the oxidation gas, thereby forming the insulation layer 111 in the form of an atomic layer. Subsequently, the remaining oxidation gas that does not participate in the chemical reaction and reaction byproducts is purged. The ALD of the insulation layer 111 may be performed at a temperature, for example, in a range of 70° C. to 350° C. Here, non-limiting examples of the silicon source gas may be selected from the group consisting of SiH₄, SiH₂Cl₂, SiHCl₃, SiCl₄, SiCl₆, Si(OC₄H₉)₄, Si(OCH₃)₄, Si(OC₂H₅)₄, SiF₄ and SiF₆, either alone or in a mixture thereof, and non-limiting examples of the oxidation gas may be selected from the group consisting of H₂O, O₂, O₃, O radical, alcohol, and H₂O₂, either alone or in a mixture thereof.

The insulation layer 111 may be formed to a thickness T₁ in a range, for example, of 5 to 10 Å.

Referring to FIG. 8, the insulation layer 111 is subjected to thermal treatment or plasma treatment to form an interface layer 112. Also, nitrogen atoms may be implanted into the insulation layer 111 with the thermal treatment or plasma treatment, thereby increasing a dielectric constant of the insulation layer 111, and further increasing the capacitance thereof. It is also possible to reduce a thickness of the insulation layer 111 necessary to improve interface characteristics while attaining a desired dielectric constant.

The interface layer 112 may be formed, for example, of a silicon oxynitride layer (SiON) obtained through the nitridation of the silicon oxide layer. In one embodiment, the nitridation may be achieved by performing a rapid thermal annealing process on the semiconductor substrate 100 having the silicon oxide layer as the insulation layer 111 while implanting a nitrogen source gas. Examples of the nitrogen source gas may be selected from the group consisting of N₂, NH₃, N₂O and NO, either alone or in a mixture thereof, and a mixed gas containing the nitrogen source gas, halogen, or an oxygen containing gas. In one embodiment, the rapid thermal annealing process is preferably performed at a temperature, for example, in a range of 500° C. to 1000° C. for a predetermined period of time, such as, for example, 10 to 30 seconds. For example, when ammonia (NH₃) is used as the nitrogen source gas, a N—H bond in ammonia is broken during the rapid thermal annealing process, and free nitrogen generated when the N—H bond in ammonia is broken is diffused into the silicon oxide layer to be combined with a weak bond and a dangling bond in the silicon oxide layer having O—Si—O bonds, thereby forming a silicon oxynitride layer.

The nitridation may be performed by plasma treatment rather than the rapid thermal annealing process. In one embodiment, plasma treatment is performed for a period of time such as, for example, 5 to 300 seconds by implanting a nitrogen source gas and applying RF source power of 100 to 1000 W, for example, while maintaining the semiconductor substrate 100 having the silicon oxide layer as the insulation layer 111 at a temperature, for example, ranging from 0° C. to 500° C. in a vacuum.

After the nitridation, the interface layer 112 may have a thickness T₂, which is greater than a thickness T₁ of the insulation layer 111. As such, in one embodiment, the interface layer 112 after nitridation has an increased thickness compared to the thickness T₁ of the insulation layer 111. The thickness of the silicon oxynitride layer 112 is increased due to regrowth of the insulation layer 111 or additional oxidation caused by free oxygens. First, during the nitridation, nitrogen atoms combine with weak bonds or dangling bonds in the insulation layer 111, allowing the insulation layer 111 to regrow. Alternatively, nitrogen atoms may break a weak Si—O bond and oxygen displacement may occur thereat, thereby allowing free oxygens to be diffused into the interface between the semiconductor substrate 100 and the silicon oxynitride layer 112, leading to additional oxidation. Accordingly, in view of the semiconductor substrate 100, an interface ‘b’ (also referred to herein as a boundary) between the semiconductor substrate 100 and the interface layer 112 is positioned below an interface ‘a’ between the semiconductor substrate 100 and the insulation layer 111 prior to the nitridation.

In one embodiment, after the nitridation, the nitrogen concentration in the interface layer 112 may be highest near the interface ‘a’ between the previously formed insulation layer 111 and the semiconductor substrate 110. This is because a region near the interface ‘b’ between the insulation layer 111 and the semiconductor substrate 100 is formed as the result of additional oxidation of the semiconductor substrate 100 and a small amount of nitrogen atoms are implanted into the region near the interface ‘b.’

Referring to FIG. 9, hydroxy groups are formed on a surface of the interface layer 112 while etching the interface layer 112. The insulation layer 111 is nitridated and the interface layer 112 having an increased thickness is etched by the above-described process, thereby reducing the thickness of the interface layer 112 while achieving a sufficiently high dielectric constant. In addition, since hydroxy groups are formed on the surface of the interface layer 112, a high-k dielectric layer deposition process to be subsequently performed may be facilitated, while improving the interface characteristics.

In one embodiment, a predetermined portion of the interface layer 112 is etched from a top surface of the interface layer 112 with an etching solution. The etching solution may be a solution capable of etching the interface layer 112 and forming hydroxy groups on the surface of the interface layer 112. For example, a mixed solution containing hydrogen peroxide and ammonium hydroxide may be used, and the mixed solution may further include deionized water. The ammonium hydroxide and hydrogen peroxide are used to etch the interface layer 112, and the hydrogen peroxide is used to form hydroxy groups on the surface of the interface layer 112.

In one embodiment, free oxygens generated when Si—O bonds in the interface layer 112 are broken during the etching are diffused into the semiconductor substrate 100 or oxygens in the mixed solution are diffused into the semiconductor substrate 100, causing some of the semiconductor substrate 100 to be additional oxidized. Accordingly, in view of the semiconductor substrate 100, a boundary ‘c’ between the interface layer 112 and the semiconductor substrate 100 may be positioned below the boundary ‘b’ between the semiconductor substrate 100 and the interface layer 112 discussed previously. However, since the top of the interface layer 112 is etched, the overall thickness T₃ of the interface layer 112 is reduced as compared to the thickness T₂ of the interface layer 112 prior to adding the hydroxy group and prior to etching.

Thus, after etching, the interface layer 112 has a thickness T₃, which is smaller than T₂ and may be, for example, 6.0 Å or less. As the surface of the interface layer 112 is saturated with hydroxy groups, the etching is not further performed, in which the case the interface layer 112 may be formed to a thickness of 6.0 Å or less.

In one embodiment, as a result of the above process, a nitrogen concentration in the interface layer 112 has a streamlined profile in which the nitrogen concentration is highest in the center of the interface layer 112. The closer to the center of the interface layer 112 from the top surface of the interface layer 112, the higher the nitrogen concentration becomes. Then, after passing a center region of the interface layer 112, the closer to the interface ‘c’ between the center of the interface layer 112 and the semiconductor substrate 100, the smaller the nitrogen concentration becomes. The interface ‘c’ may be, for example, a boundary where above the boundary a certain percentage of nitrogen is included at a particular height, and below the boundary, a certain, lower percentage of nitrogen is included at a different height.

The streamlined profile is demonstrated, in one embodiment, because the nitrogen concentration is highest at a region near the interface ‘b’ between the interface layer 112 and the semiconductor substrate 100 before the etching and the nitridating and the interface ‘b’ is shifted downward at the same time when the interface layer 112 is etched. Compared to a case when the nitrogen concentration is relatively high around the interface ‘c,’ when the nitrogen concentration is uniformly distributed around the interface ‘c,’ a higher dielectric constant can be achieved while improving interface characteristics. Thus, the dielectric constant and the interface characteristics can further be improved as the result of etching.

Alternatively, the nitrogen concentration may also be controlled by the etching. For example, as the etching time is extended, an increased amount of the interface layer 112 is etched, thereby reducing the nitrogen concentration. The etching time may be arbitrarily adjusted by one skilled in the related art in consideration of the nitrogen concentration.

Referring to FIG. 10, a high-k dielectric layer 113 may be formed on the interface layer 112.

The high-k dielectric layer 113 may serve, for example, as a gate insulation layer together with the interface layer 112. The use of the high-k dielectric layer 113 allows a gate insulation layer having a reduced thickness while achieving a sufficiently high dielectric constant. In the manufacturing method according to certain disclosed embodiments, since hydroxy groups are formed on the top surface of the interface layer 112, deposition of the high-k dielectric layer 113 is facilitated and the interface characteristics are improved, thereby preventing leakage current.

Non-limiting examples of the high-k dielectric layer 113 may include hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate, either alone or in a mixture thereof. In addition, the high-k dielectric layer 31 may have a single or multiple layered structure including the above stated materials, and the structure type or thickness of the high-k dielectric layer 113 may be arbitrarily adjusted by one skilled in the related art so long as they do not negate the advantages of the disclosed embodiments.

The high-k dielectric layer 113 may be formed, in certain embodiments, by atomic layer deposition (ALD) or chemical vapor deposition (CVD). In one embodiment, the high-k dielectric layer 113 is formed by atomic layer deposition as follows. The semiconductor substrate 100 having the interface layer 112 is loaded into an ALD equipment. Next, a metal source gas, a purge gas, a reaction gas and additional purge gas are sequentially supplied to the ALD equipment. The metal source gas may use an organometallic compound as a precursor. In an exemplary embodiment, when the high-k dielectric layer 113 is formed of a hafnium oxide layer, examples of the metal source gas may include one selected from the group consisting of Cl₆H₃₆HfO₄, TEMAH(Hf[NC₂H₅CH₃]₄), TDMAH(Hf[N(CH₃)₂]₄), and TDEAH(Hf[N(C₂H₅)₂]₄), either alone or in a mixture thereof. The organometallic compound containing hafnium is supplied to be adsorbed onto the interface layer 112, and the purge gas is then supplied to remove the remaining gas that is not adsorbed. Here, adsorption of the metal source gas can be uniformly achieved by the hydroxy groups formed on the interface layer 112, thereby improving the interface characteristics. N₂ gas or argon (Ar) gas may be used as the purge gas. Next, the reaction gas selected from the group consisting of ozone (O₃), plasma oxygen, or water vapor (H₂O), either alone or in a mixture thereof, is supplied to react with hafnium adsorbed onto the interface layer 112, thereby forming a hafnium oxide layer. Next, a purge gas is additionally injected to remove unreacted gas. The above-described processing steps may be continuously repeated a number of times, thereby forming the high-k dielectric layer 113. In addition, a thickness of the high-k dielectric layer 113 may be adjusted by adjusting the number of times repeated. If the high-k dielectric layer is a composite layer including two or more metals, for example, the two or more metals of the metal source gas may be simultaneously supplied. Alternatively, after the reaction gas is injected, a second metal source gas may be injected.

Referring to FIG. 11, a conductive layer 114 may be formed on the high-k dielectric layer 113. For example, the conductive layer 114 may be formed on the high-k dielectric layer 113 by chemical vapor deposition or sputtering, which is then patterned to be formed as a gate electrode.

The conductive layer 114 may be formed of a single layer of a metal or other conductor, such as polysilicon (poly-Si), poly-SiGe, doped poly-Si, Ta, TaN, TaSiN, TiN, Mo, Ru, Ni or NiSi, or metal silicide, or a stacked layer of combinations of these conductors, but not limited thereto. If the conductive layer 114 is formed of a metal or metal silicide, low resistance can be achieved on a fine line width while not necessitating impurity doping. Alternatively, the conductive layer 114 may also be formed of a single layer of polysilicon (poly-Si), a metal, metal silicide or metal nitride, or a stacked layer of more than one of these materials. Non-limiting examples of the metal may include tungsten (W), cobalt (Co), nickel (Ni), titanium (Ti), tantalum (Ta) or alloys thereof. In a case where the conductive layer 114 is formed of a poly-Si layer, the conductive layer 114 may be formed by directly depositing poly-Si on the high-k dielectric layer 113 by low pressure chemical vapor deposition (LPCVD), or plasma enhanced CVD. Alternatively, amorphous silicon is deposited on the high-k dielectric layer 113 and crystallization is followed by annealing, thereby forming the conductive layer 114 formed of a poly-Si layer.

Referring to FIG. 12, an insulation layer 115 for a hard mask layer, which is to be briefly referred as a hard mask insulation layer, may be formed on the conductive layer 114. The hard mask insulation layer 115 may become a hard mask layer to then protect the gate electrode.

The hard mask insulation layer 115 may also be formed of silicon nitride (SiN) or silicon oxynitride (SiON), but is not limited thereto. In addition, the hard mask insulation layer 115 may be formed by CVD or ALD. The forming of the hard mask insulation layer 115 may be skipped by one skilled in the related art as desired.

Referring to FIG. 13, the interface layer 112, the high-k dielectric layer 113, the conductive layer 114 and the hard mask insulation layer 115 are patterned, thereby forming a gate pattern 110.

For example, a photoresist layer (not shown) may be formed on the hard mask insulation layer 115 and a photomask (not shown) is disposed on the photoresist layer. The photomask includes a light-shielding portion and a light-transmitting portion, and for the convenience of explanation, the following description will be made with regard to a positive-type photoresist layer by way of example. However, the photoresist layer of the present invention is not limited to the illustrated positive-type photoresist layer and a negative-type photoresist layer may also be used. The photomask is disposed on the photoresist layer such that the light-shielding portion corresponds to a potential region where the gate pattern is to be formed. Next, light is irradiated into the photoresist layer through the photomask and the photoresist layer is then developed, thereby forming a photoresist pattern. The interface layer 112, the high-k dielectric layer 113, the conductive layer 114 and the hard mask insulation layer 115 are etched using the photoresist pattern as an etch mask and the photoresist pattern is removed, thereby forming the gate pattern 110. The etching may be either dry etching or wet etching. In the wet etching, phosphoric acid, nitric acid or acetic acid may be used as an etching solution. In the dry etching, chlorine-based etching gas, for example, Cl₂ or BCl₃, may be used.

Referring to FIG. 14, impurity ions are doped into the semiconductor substrate 100 using the gate pattern 110 as a mask to form a lightly doped impurity region 131, and a gate spacer 121 is then formed. Next, source and drain regions 132 are formed.

The lightly doped impurity region 131 is formed by doping impurity ions into the semiconductor substrate 100 of both sidewalls of the gate pattern 110 in a low concentration using the gate pattern 110 as a mask. The lightly doped impurity region 131 is doped with a smaller concentration of impurities than the source and drain regions 132 and mitigates an electric field in the source and drain regions 132 while reducing leakage current.

The impurities may be doped by an ion implantation process. Specifically, as an example, n-type impurity such as phosphorus (P) or arsenic (As) may be doped in a case of an NMOS region, and p-type impurity such as boron (B), borondifluoride (BF₂) or gallium (Ga) may be doped in a case of a PMOS region.

The gate spacer 121 is formed on the sidewalls of the gate pattern 110 to protect the gate electrode 122. The gate spacer 121 may have, for example, a single layer structure of a silicon nitride layer or a silicon oxide layer, or a multi-layered structure of a combination of these layers. FIG. 14 illustrates a case where the gate spacer 121 is formed of a single layer.

The source and drain regions 132 are spaced apart from each other in view of the gate pattern 110 and the gate spacer 121 and are formed by doping impurity ions in a high concentration using the gate pattern 110 and the gate spacer 121 as masks. Specifically, the source and drain regions 132 may be formed by doping impurities such as phosphorus (P) or arsenic (As) as an n-type dopant in a case of an NMOS region, and impurity such as boron (B) or gallium (Ga) as a p-type dopant in a case of a PMOS region.

Although not shown, the source and drain regions 132 may have an elevated structure formed above the semiconductor substrate 100. A projected range (Rp) is formed on a top surface of the semiconductor substrate 100 due to impurity doping in the elevated source and drain structure. Accordingly, deterioration of device characteristics due to a short channel effect can be prevented.

As described above, in the manufacturing method of the semiconductor device according to certain embodiments, a gate dielectric layer having a dual layered structure consisting of the interface layer 112 and the high-k dielectric layer 113 has a reduced thickness while achieving a sufficiently high dielectric constant. In addition, in the manufacturing method of the semiconductor device according to the disclosed embodiments, the interface layer 112 is formed between the high-k dielectric layer 113 and the semiconductor substrate 100, thereby improving interface characteristics therebetween while reducing leakage current. Since the interface layer 112 contains nitrogen atoms and hydroxy groups formed on its surface, it has a high dielectric constant, compared to a case where a silicon oxide layer is formed, the capacitance of device can be increased, and deposition of the high-k dielectric layer 113 can be facilitated. Further, in the manufacturing method of the semiconductor device according to the disclosed embodiments, the concentration of nitrogen atoms implanted into the interface layer 112 can be arbitrarily adjusted.

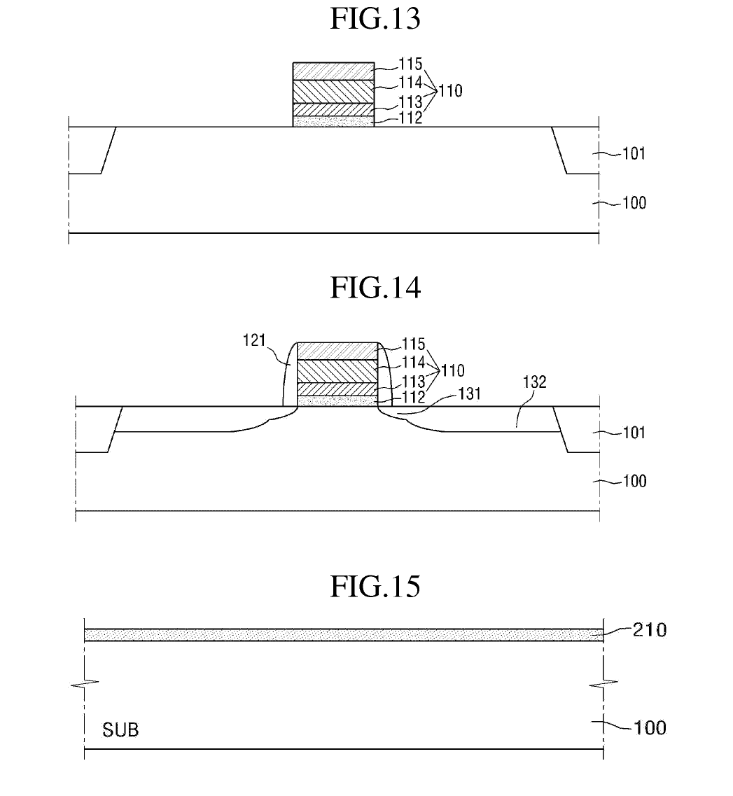

Hereinafter, a manufacturing method for a semiconductor device according to another embodiment will be described with reference to FIGS. 15 to 17.

FIGS. 15 to 17 are cross-sectional views sequentially illustrating processing steps of a manufacturing method for a semiconductor device according to another embodiment.

Referring to FIG. 15, a first insulation layer 210 is formed on a substrate 100.

The substrate 100 may be, for example, a silicon substrate, a silicon on insulator (SOI) substrate, or a silicon germanium substrate, but is not limited thereto.

The first insulation layer 210 may be, for example, a silicon oxide layer. Specifically, the first insulation layer 210 may be formed by performing thermal oxidation on the substrate 100 or performing a rapid thermal oxidation at a temperature of 700 to 1100° C. at the oxygen atmosphere, but is not limited thereto. The oxygen atmosphere may be created by implanting hydrogen peroxide (H₂O₂), ozone (O₃) or water (H₂O), for example. Alternatively, the first insulation layer 210 may be formed by treating the substrate 100 with a chemical material. In detail, the substrate 100 may be treated with a solution containing an oxygen source and ammonia (NH₃) to oxidize the upper region of the substrate 100 by the oxygen source, thereby forming the first insulation layer 210. Here, hydrogen peroxide may be used as the oxygen source, but it is not limited thereto. In addition, the first insulation layer 210 may be formed by atomic layer deposition (ALD) or chemical vapor deposition (CVD). Here, non-limiting examples of a silicon source gas may include at least one selected from the group consisting of SiH₄, SiH₂Cl₂, SiHCl₃, SiCl₄, Si(OC₄H₉)₄, Si(OCH₃)₄ and Si(OC₂H₅)₄, either alone or in a mixture thereof, and non-limiting examples of a oxygen source gas may include at least one selected from the group consisting of H₂O, O₂, O₃, O radical, alcohol, and H₂O₂, either alone or in a mixture thereof.

Referring to FIG. 16, the first insulation layer 210 is subjected to thermal treatment or plasma treatment to form a second insulation layer 220. Specifically, the thermal treatment is performed at a temperature in a range of 500° C. to 1300° C. in an inert gas atmosphere or oxygen-containing gas atmosphere. The thermal treatment is for example, a rapid thermal annealing, furnace annealing, laser annealing, spike annealing or flash annealing, but is not limited thereto. The plasma treatment is performed for a time period such as, for example, 5 to 300 seconds applying RF source power of, for example, 100 to 1000 W while maintaining the substrate 100 having the first insulation layer 210 at a temperature, for example, ranging from 0° C. to 500° C. in a vacuum.

Referring to FIG. 17, hydroxy groups are formed on a surface of the second insulation layer 220. In one embodiment, for example, the second insulation layer 220 is treated chemically by a mixed solution containing hydrogen peroxide and ammonium hydroxide, thereby the hydroxy groups are formed on the surface of the second insulation layer 210. Here, the upper portion of the second insulation layer 220 is etched while the hydroxy group is formed on the surface of the second insulation layer 220. Since hydroxy groups are formed on the surface of the second insulation layer 220, a high-k dielectric layer deposition process to be subsequently performed may be facilitated, while improving the interface characteristics.

Hereinafter, merits and advantageous effects of the present embodiments will be described in more detail through the following examples.

### Experimental Example 1

### Evaluation of Nitrogen Concentration and Interface Layer Thickness

### 1-1. Example 1

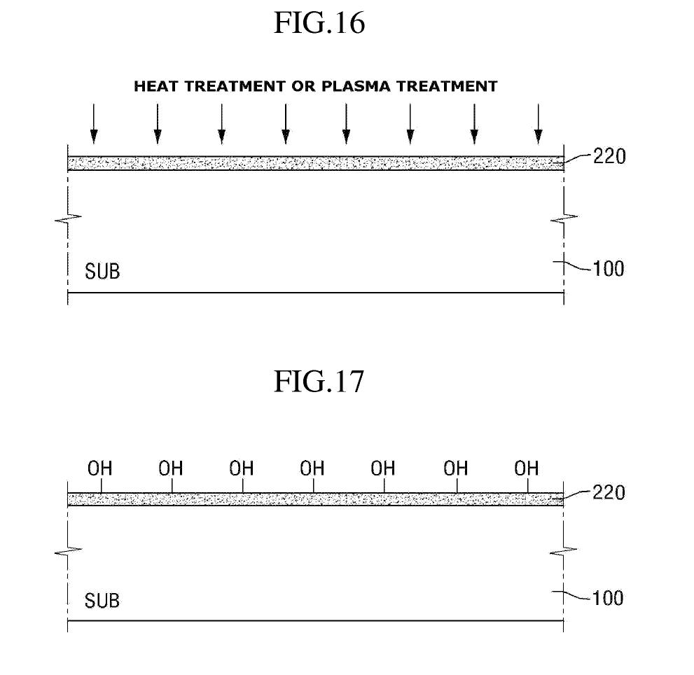

A silicon substrate was oxidized in an ozone (O₃) atmosphere to form a silicon oxide layer and nitrogen atoms were implanted into the silicon oxide layer by performing a rapid thermal annealing process at 700° C. for approximately 10 seconds while supplying ammonia (NH₃) to the silicon substrate having the silicon oxide layer. As a result, a silicon oxynitride (SiON) layer having a thickness of approximately 16 Å was formed. Accordingly, the nitrogen concentration of the interface layer and the interface layer thickness were measured over the treatment time while treating the silicon oxynitride layer with an SC1 (standard clean 1) solution containing a mixture of ammonium hydroxide and hydrogen peroxide, and the measurement result is shown in FIG. 18.

### 1-2. Example 2

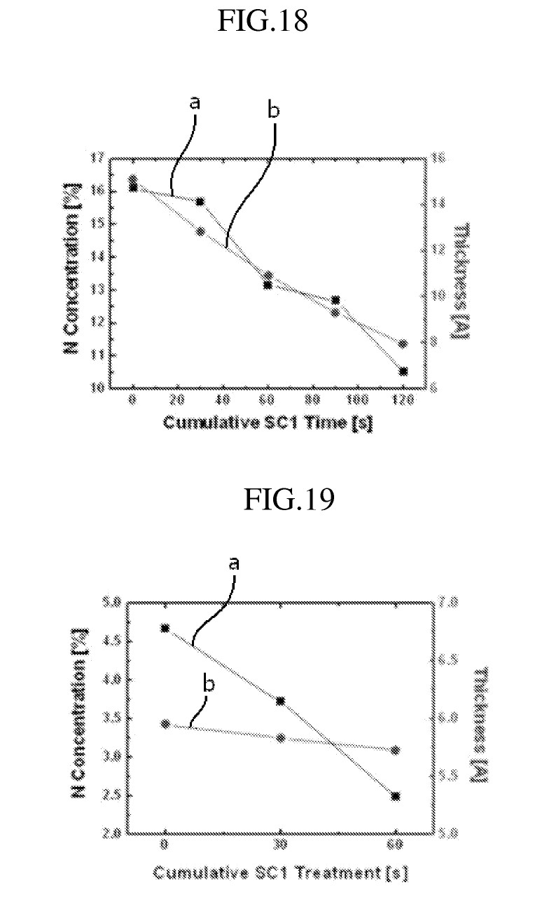

A silicon oxide layer was formed in substantially the same manner as in Example 1, except that a silicon substrate was oxidized using an SC1 solution containing a mixture of ammonium hydroxide and hydrogen peroxide and the silicon oxide layer was formed to a thickness of approximately 6.0 Å. The nitrogen concentration (i.e., average concentration within the silicon oxynitride layer) and silicon oxynitride layer thickness were measured over the treatment time while treating the silicon oxynitride layer with an SC1 (standard clean 1) solution containing a mixture of ammonium hydroxide and hydrogen peroxide, and the measurement result is shown in FIG. 19. In FIG. 18 and FIG. 19, graph a represents the nitrogen concentration with treatment time and graph b represents the silicon oxynitride layer thickness with treatment time.

The rectangular label represents nitrogen concentration and circle label represents thickness of the silicon oxynitride layer in FIGS. 18 and 19. As shown in FIGS. 18 and 19, as the treatment time increased, the nitrogen concentration decreased and the silicon oxynitride layer thickness was also reduced. In Example 1, after the silicon oxynitride layer having a thickness of approximately 16 Å was etched with an SC-1 solution for approximately 120 seconds, the thickness of the silicon oxynitride layer of approximately 8 Å, demonstrating a thickness reduction of approximately 50%. In Example 2, an initial thickness of the silicon oxynitride layer, before etching, was approximately 6.0 Å, and a considerable reduction in the thickness of the silicon oxynitride layer was not demonstrated even after the etching for approximately 60 seconds. Accordingly, it could be understood that the thickness of the silicon oxynitride layer was not further reduced once it came to approximately 5.0 to 6.0 Å. It was also understood that the nitrogen concentration could be adjusted by adjusting the etching time because the nitrogen concentration is reduced as the etching time is extended.

The manufacturing methods described herein could be used for various types of semiconductor devices. For example, it may be used to form transistors in different types of semiconductor memory chips (e.g., flash memory, DRAM, SRAM, etc.), in semiconductor logic chips, or for other semiconductor devices. In addition, the semiconductor device described herein may be part of a single chip, a semiconductor package, a package-on-package device, a semiconductor module such as a memory module, etc. As such, the manufacturing methods can be used to form a plurality of transistors on a substrate or chip that form, for example, a memory array or other integrated circuit.

While the present disclosure has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A method of manufacturing a semiconductor device, the method comprising:
forming a silicon oxide layer on a base layer including silicon;
forming a silicon oxynitride layer by implanting nitrogen into the silicon oxide layer; and
forming hydroxy groups on a surface of the silicon oxynitride layer while etching the silicon oxynitride layer.

2. The method of claim 1, wherein the forming of the silicon oxynitride layer comprises performing a rapid thermal annealing process while implanting a nitrogen source gas into the silicon oxide layer.

3. The method of claim 2, wherein the nitrogen source gas is ammonia.

4. The method of claim 1, wherein the forming of the hydroxy groups comprises treating the silicon oxynitride layer using a mixed solution containing hydrogen peroxide and ammonium hydroxide.

5. The method of claim 5, wherein after the silicon oxynitride layer is treated with the mixed solution, the silicon oxynitride layer has a thickness of 6 Å or less.

6. The method of claim 1, further comprising forming a high-k dielectric layer on the silicon oxynitride layer.

7. The method of claim 10, wherein the high-k dielectric layer is formed by atomic layer deposition.

8. A method of manufacturing a semiconductor device, the method comprising:
forming an insulation layer on a substrate;
forming an interface layer by thermal treatment or plasma treatment to the insulation layer;
forming hydroxy groups on a surface of the interface layer by treating the interface layer using an etching solution containing an oxygen source;
forming a high-k dielectric layer on the interface layer;
forming a conductive layer on the high-k dielectric layer; and
forming a gate pattern by patterning the interface layer, the high-k dielectric layer and the conductive layer.

9. The method of claim 8, wherein the forming of the interface layer comprises implanting nitrogen into the insulation layer by performing a rapid thermal annealing process at a temperature in a range of 500° C. to 1000° C. for 10 to 30 seconds.

10. The method of claim 8, wherein the forming of the insulation layer comprises oxidizing a predetermined region of the semiconductor substrate by treating a mixed solution including an oxygen source and ammonium hydroxide.

11. The method of claim 10, wherein the oxygen source is hydrogen peroxide.

12. The method of claim 8, wherein the etching solution includes hydrogen peroxide and ammonium hydroxide.

13. The method of claim 8, wherein the high-k dielectric layer is formed by atomic layer deposition.

14. The method of claim 8, wherein forming hydroxy groups comprises reducing a thickness of the interface layer while treating with the etching solution containing an oxygen source to form hydroxy groups on interface layer's surface.

15. The method of claim 8, wherein a width of the interface layer after performing etching is between 5 Å and 10 Å.

16. A method of manufacturing a semiconductor device, the method comprising:
forming an insulation layer on a substrate; and
forming hydroxy groups on a surface of the insulation layer.

17. The manufacturing method of claim 16, wherein forming the insulation layer comprises:
forming a first insulation layer on the substrate; and
forming a second insulation layer by performing a thermal treatment or plasma treatment to the first insulation layer.

18. A method of forming a semiconductor device, the method comprising:
forming a first interface layer on a substrate, the first interface layer including nitrogen;
forming a second interface layer on the substrate by forming hydroxy groups on a surface of the first interface layer and by treating the first interface layer using an etching solution containing an oxygen source, wherein a distance between a peak nitrogen concentration at a first height within the first interface layer and a midpoint of the height of the first interface layer is greater than a distance between a peak nitrogen concentration at a second height within the second interface layer and a midpoint of the height of the second interface layer;
forming a high-k dielectric layer on the second interface layer;
forming a conductive layer on the high-k dielectric layer; and
forming a gate pattern by patterning the second interface layer, the high-k dielectric layer and the conductive layer.

19. The method of claim 18, further comprising:
forming the first interface layer by forming an insulation layer on the substrate and performing thermal treatment or plasma treatment to the insulation layer.

20. The method of claim 18, wherein forming hydroxy groups comprises reducing a thickness of the second interface layer while treating with the etching solution containing an oxygen source to form hydroxy groups on the second interface layer's surface.
